(19) United States
(12) Patent Application Publication
(10) Pub. No.: US 2012/0193707 A1
(43) Pub. Date: Aug. 2, 2012

(54) High voltage multigate device and manufacturing method thereof

(75) Inventors: Tsung-Yi Huang, Hsinchu City (TW); Chien-Wei Chiu, Beigang Township (TW)

(73) Assignee: Richtek Technology Corporation, R.O.C.

(21) Appl. No.: 13/065,569

(22) Filed: Mar. 24, 2011

(30) Foreign Application Priority Data
Jan. 28, 2011 (TW) 100103418

(51) Int. Cl. H01L 29/78; H01L 21/336

(52) U.S. Cl. 257/335; 438/283; 257/E29.256; 257/E29.264; 257/E21.417; 257/E21.421

(57) ABSTRACT

The present invention discloses a high voltage multigate device and a manufacturing method thereof. The high voltage multigate device includes: a semiconductor fin doped with first conductive type impurities; a dielectric layer, which overlays a portion of the semiconductor fin; a gate which overlays the dielectric layer; a drain doped with second conductive type impurities, which is formed in the semiconductor fin or coupled to the semiconductor fin; a source doped with second conductive type impurities, which is formed in the semiconductor fin or coupled to the semiconductor fin, wherein the drain and the source are located at different sides of the gate; and a drift region or a well doped with second conductive type impurities, which is formed in the semiconductor fin at least between the drain and the gate.

### CROSS-REFERENCE

The present invention claims priority to TW 100103418, filed on Jan. 28, 2011.

### BACKGROUND OF THE INVENTION

1. Field of Invention

The present invention relates to a high voltage multigate device and its manufacturing method.

2. Description of Related Art

FIGS. 1-3 respectively show, by cross-section view, schematic diagrams of three high voltage devices. FIG. 1 shows a cross-section view of a double diffused metal oxide semiconductor (DMOS) device which is manufactured by the following steps: forming an isolation structure 12 in a P-type substrate 11 to define a first device region 100, wherein the isolation structure 12 is formed by, for example, local oxidation of silicon (LOCOS); forming an N-type well region 17 in the substrate 11; and forming a gate 13, a source 14, a drain 15, and a body region 16 in the first device region 100. FIG. 2 shows a cross-section view of a lateral double diffused metal oxide semiconductor (LDMOS) device which is manufactured by the following steps: forming an isolation structure 12 in a P-type substrate 11 to define a first device region 100 and a second device region 200, wherein the isolation structure 12 is, for example, the LOCOS structure; forming a gate 13 on the substrate 11; forming a source 14 in the first device region 100; forming a drain 15 in the second device region 200; and forming an N-type drift region 18 surrounding the drain 15 to separate the source 14 from the drain 15. FIG. 3 shows a cross-section view of a double diffused drain metal oxide semiconductor (DDDMOS) device which is manufactured by the following steps: forming an isolation structure 12 in a P-type substrate 11 to define a first device region 100, wherein the isolation structure 12 is, for example, the LOCOS structure; and forming a gate 13, a source 14, a drain 15, and a drift region 18 in the first device region 100.

In device characteristics with respect to gate control, that is, device characteristics with respect to device on/off behavior, the three high voltage devices mentioned above require a better design to reduce their conduction resistance and leakage current.

In the view of above, to overcome the drawback in the prior art, the present invention proposes a high voltage multigate device and its manufacturing method to improve the device characteristics so that the device provides a broader range of applications.

### SUMMARY OF THE INVENTION

The objective of the present invention is to provide a high voltage multigate device and its manufacturing method.

To achieve the foregoing objective, in one perspective of the present invention, it provides a high voltage multigate device comprising: a semiconductor fin doped with first conductive type impurities; a dielectric layer overlaying a portion of the semiconductor fin; a gate overlaying the dielectric layer; a drain doped with second conductive type impurities, the drain being formed in the semiconductor fin or coupled to the semiconductor fin; a source doped with second conductive type impurities, the source being formed in the semiconductor fin or coupled to the semiconductor fin, wherein the drain and the source are located at different sides of the gate; and a first drift region or a well doped with second conductive type impurities, the first drift region or the well being formed in the semiconductor fin at least between the drain and the gate.

In another perspective of the present invention, it provides a method for manufacturing a high voltage multigate device, comprising: forming a semiconductor fin doped with first conductive type impurities; forming a dielectric layer overlaying a portion of the semiconductor fin; forming a gate overlaying the dielectric layer; forming a drain doped with second conductive type impurities in the semiconductor fin or coupled to the semiconductor fin; forming a source doped with second conductive type impurities in the semiconductor fin or coupled to the semiconductor fin, wherein the drain and the source are located at different sides of the gate; and forming a first drift region or a well doped with second conductive type impurities in the semiconductor fin at least between the drain and the gate.

The foregoing high voltage multigate device may be a planar device or a vertical device, that is, the source and the drain may be located on the same plane or on different planes.

The foregoing high voltage multigate device may be a symmetric or asymmetric device. When the high voltage multigate device is a symmetric device, it further includes a second drift region with second conductive type impurities, the second drift region being formed in the semiconductor fin at least between the source and the gate.

The objectives, technical details, features, and effects of the present invention will be better understood with regard to the detailed description of the embodiments below, with reference to the drawings.

### BRIEF DESCRIPTION OF THE DRAWINGS

FIGS. 1-3 respectively show, by cross-section view, schematic diagrams of three kinds of high voltage devices.

FIGS. 4A-4F show a first embodiment of the present invention.

FIGS. 5A and 5B show a second embodiment of the present invention.

FIGS. 6A and 6B show a third embodiment of the present invention.

FIGS. 7A and 7B show a fourth embodiment of the present invention.

FIGS. 8A and 8B show a fifth embodiment of the present invention.

FIGS. 9A and 9B show a sixth embodiment of the present invention.

FIGS. 10A and 10B show a seventh embodiment of the present invention.

FIG. 11 shows an eighth embodiment of the present invention.

### DESCRIPTION OF THE PREFERRED EMBODIMENTS

The drawings as referred to throughout the description of the present invention are for illustration only, to show the interrelations between the layers/parts, but not drawn according to actual scale.

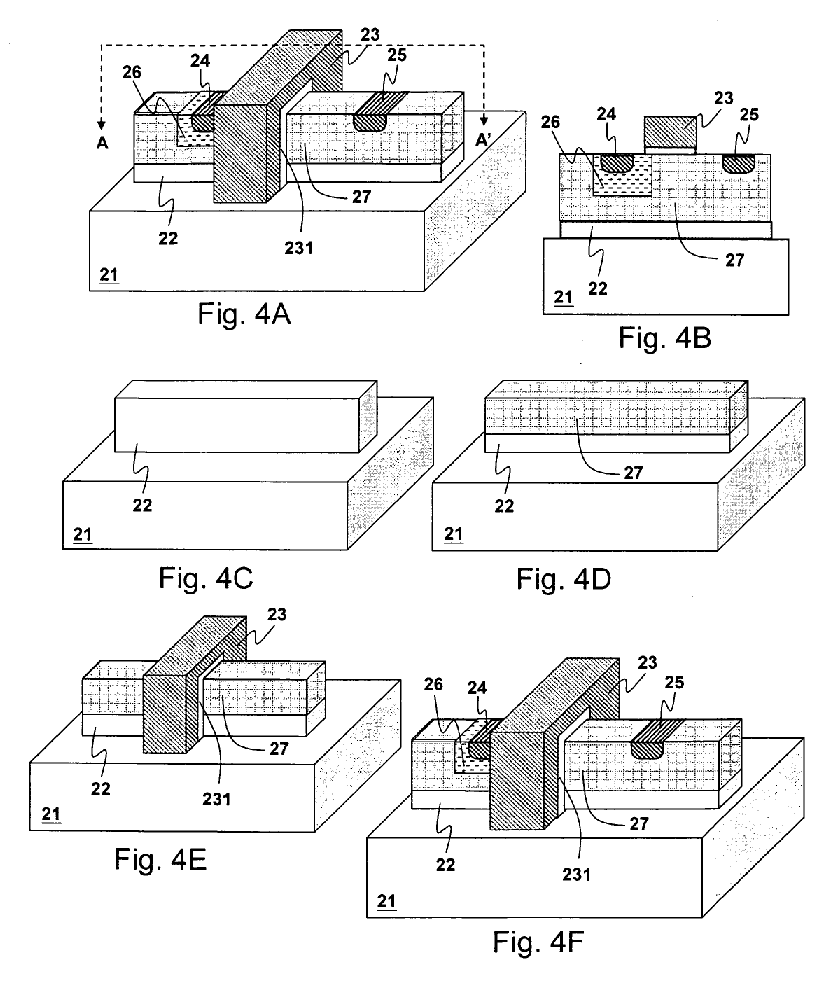

Please refer to FIGS. 4A-4F for a first embodiment of the present invention. FIG. 4A illustrates a three-dimensional schematic diagram of a high voltage multigate DMOS device according to the present invention. FIG. 4B illustrates a cross-section view taken along the cross-section line AA′ of FIG. 4A. FIGS. 4C-4F illustrate a manufacturing process of the high voltage multigate DMOS device. Referring to FIG. 4C, a substrate 21 is provided and it may be, for example, a SOI (Silicon On Insulator) substrate or a silicon substrate, and a semiconductor fin 22 doped with first conductive type impurities is formed on the substrate 21, wherein the first conductive type impurities may be, for example but not limited to, P-type impurities. Next, as shown in FIG. 4D, the semiconductor fin 22 is doped with second conductive type impurities which may be, for example but not limited to, N-type impurities, to form a second conductive type well region 27.

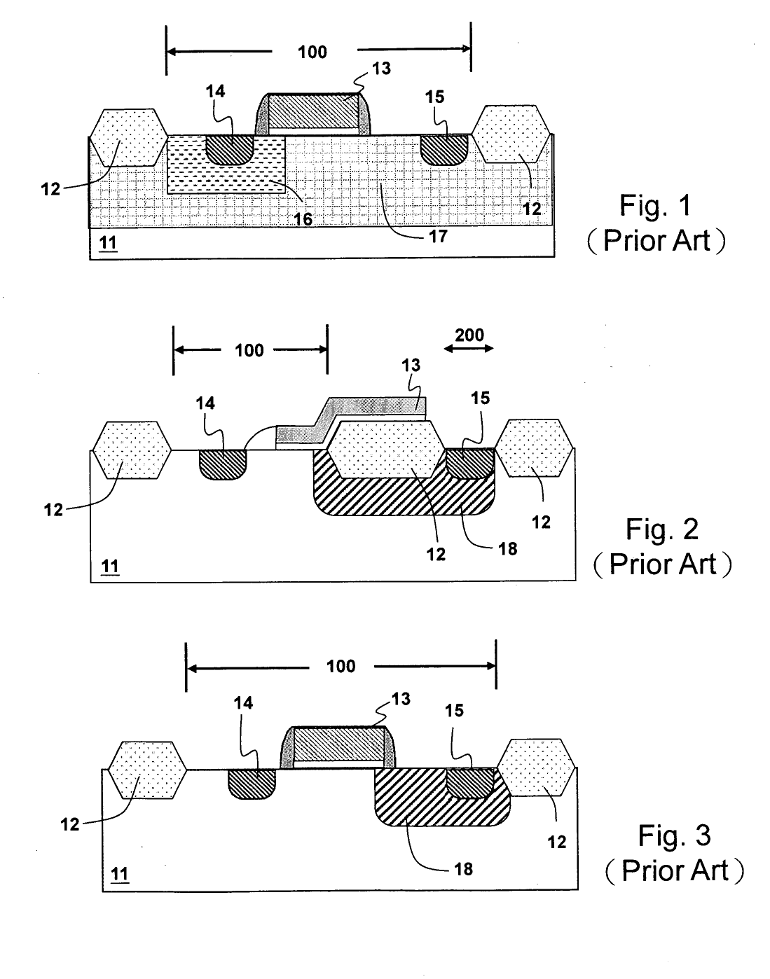

Next, as shown in FIG. 4E, a dielectric layer 231 and a gate 23 are formed on the substrate 21, wherein the dielectric layer 231 overlays a portion of the semiconductor fin 22 and the gate 23 overlays the dielectric layer 231. Next, as shown in FIG. 4F, a pattern is defined by lithography and the gate 23, and an ion implantation process is performed to form a body region 26 with the first conductive type impurities which may be, for example but not limited to, P-type impurities. Next, another pattern is defined by lithography and the gate 23, and another ion implantation process is performed to form a source 24 and a drain 25 with the second conductive type impurities which may be, for example but not limited to, N-type impurities. The second conductive type well region 27 separates the drain 25 from the gate 23, but it also couples the drain 25 to the gate 23 to form a channel as the device is turned on; the body region 26 separates the source 24 from the gate 23, and surrounds the source 24. As such, the high voltage multigate DMOS device is completed, which has better device characteristics compared to the prior art device shown in FIG. 1.

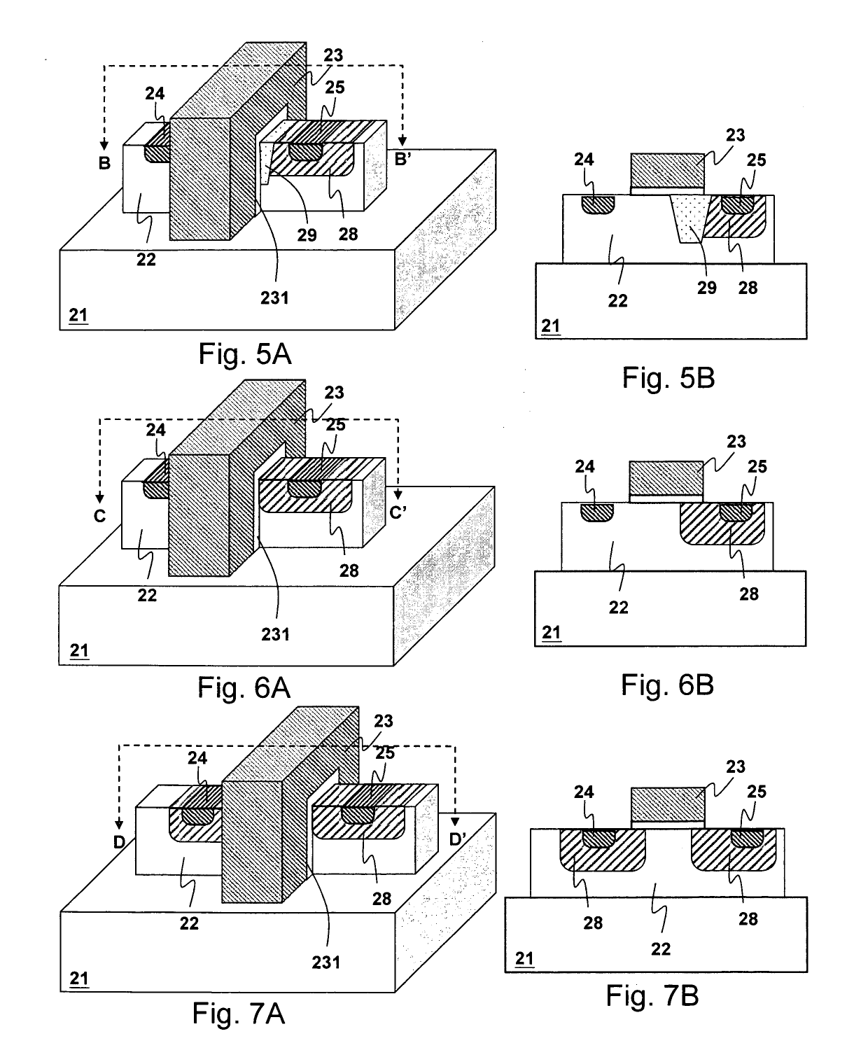

FIGS. 5A and 5B show a second embodiment of the present invention. FIG. 5A illustrates a three-dimensional schematic diagram of a high voltage multigate LDMOS device. FIG. 5B illustrates a cross-section view taken along the cross-section line BB′ of FIG. 5A. This second embodiment is different from the first embodiment in that there are no second conductive type well region 27 and body region 26 formed in the semiconductor fin 22; instead, a second conductive type drift region 28 separating the drain 25 from the gate 23, and an isolation structure 29 partially or totally in a region surrounded by the gate 23, are formed in the semiconductor fin 22. The high voltage multigate LDMOS device of this embodiment has better device characteristics compared to the prior art device shown in FIG. 2.

FIGS. 6A and 6B show a third embodiment of the present invention. This embodiment is similar to the second embodiment, but it is applied to a high voltage multigate DDDMOS device. FIG. 6A illustrates a three-dimensional schematic diagram of the high voltage multigate DDDMOS device. FIG. 6B illustrates a cross-section view taken along the cross-section line CC′ of FIG. 6A. This third embodiment is different from the second embodiment in that there is no isolation structure 29 formed in the semiconductor fin 22. But similar to the second embodiment, the second conductive type drift region 28 is formed in the semiconductor fin 22.

FIGS. 7A and 7B show a fourth embodiment of the present invention. This embodiment is similar to the third embodiment, but it is applied to a symmetric high voltage multigate DDDMOS device. FIG. 7A illustrates a three-dimensional schematic diagram of the symmetric high voltage multigate DDDMOS device. FIG. 7B illustrates a cross-section view taken along the cross-section line DD′ of FIG. 7A. This fourth embodiment is different from the third embodiment in that, there are two second conductive type drift regions 28 formed in the semiconductor fin 22; one separates the drain 25 from the gate 23 while the other separates the source 24 from the gate 23.

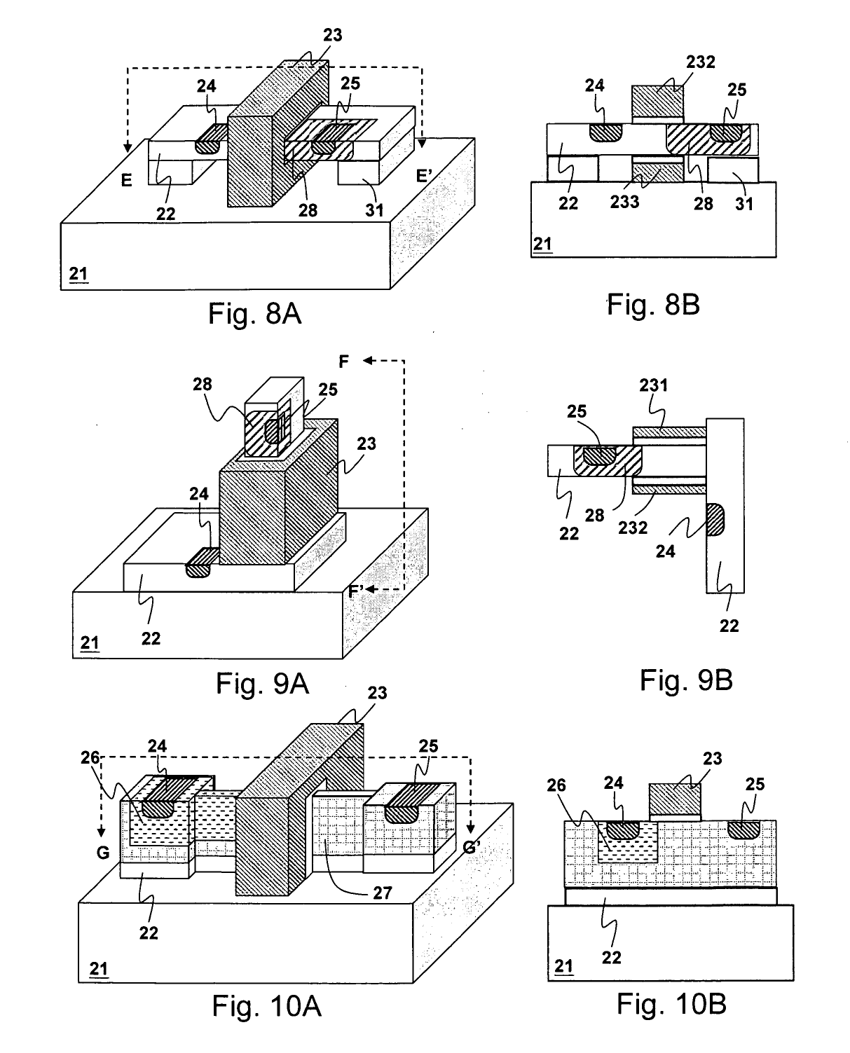

FIGS. 8A and 8B show a fifth embodiment of the present invention. This embodiment is similar to the third embodiment, but it is applied to a planar high voltage dual-gate DDDMOS device. FIG. 8A illustrates a three-dimensional schematic diagram of the planar high voltage dual-gate DDDMOS device. FIG. 8B illustrates a cross-section view taken along the cross-section line EE′ of FIG. 8A. In this embodiment, the gate 23 includes two gate plates 232 and 233 respectively located at the upside and downside of the semiconductor fin 22, instead of the front and rear sides of the semiconductor fin 22 as in the third embodiment. In addition, a support layer 31 is provided between the semiconductor fin 22 and the substrate 21 to support the semiconductor fin 22.

FIGS. 9A and 9B show a sixth embodiment of the present invention. This embodiment is similar to the third embodiment, but it is applied to a vertical high voltage dual-gate DDDMOS device. FIG. 9A illustrates a three-dimensional schematic diagram of the vertical high voltage dual-gate DDDMOS device. FIG. 9B illustrates a cross-section view taken along the cross-section line FF′ of FIG. 9A. In this embodiment, the source 24 and the drain 25 are located at different sides of the gate 23, and the two gate plates 232 and 233 of the gate 23 are located at the upside and downside of the semiconductor fin 22 instead of the front and rear sides of the semiconductor fin 22 as in the third embodiment.

The DDDMOS devices of the third to sixth embodiments have better device characteristics compared to the prior art device shown in FIG. 3.

FIGS. 10A and 10B show a seventh embodiment of the present invention. FIG. 10A illustrates a three-dimensional schematic diagram of the high voltage multigate DMOS device. FIG. 10B illustrates a cross-section view taken along the cross-section line GG′ of FIG. 10A. This embodiment is similar to the first embodiment, but the source 24 and the drain 25 of the DMOS device are connected to the semiconductor fin 22 instead of being inside the semiconductor fin 22.

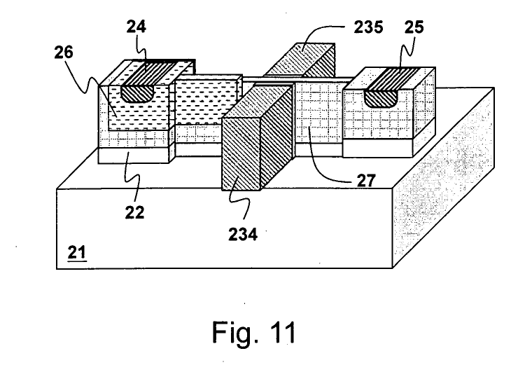

FIG. 11 shows an eighth embodiment of the present invention. This eighth embodiment is different from the seventh embodiment in that, the gate 23 in this DMOS device includes multiple separated gate plates which may be, for example but not limited to, two gate plates 234 and 235 shown in FIG. 11. This embodiment shows that in the high voltage multigate device according to the present invention, the gate 23 may include multiple separated gate plates which can be controlled separately and individually.

The DMOS devices of the seventh and eighth embodiments have better device characteristics compared to the prior art device shown in FIG. 1.

The present invention has been described in considerable detail with reference to certain preferred embodiments thereof. It should be understood that the description is for illustrative purpose, not for limiting the scope of the present invention. Those skilled in this art can readily conceive variations and modifications within the spirit of the present invention. For example, other manufacturing process steps or structures which do not affect the characteristics of the devices, such as a deep-well region, etc., can be added. As another example, the lithography is not limited to photolithography; it can be electron beam lithography, X-ray lithography or other methods. As yet another example, the present invention also can be applied to other types of multigate devices, such as a gate with a drum-shaped structure. Thus, the present invention should cover all such and other modifications and variations, which should be interpreted to fall within the scope of the following claims and their equivalents.

What is claimed is:

1. A high voltage multigate device, comprising:
a semiconductor fin doped with first conductive type impurities;
a dielectric layer overlaying a portion of the semiconductor fin;
a gate overlaying the dielectric layer;
a drain doped with second conductive type impurities, the drain being formed in the semiconductor fin or coupled to the semiconductor fin;
a source doped with second conductive type impurities, the source being formed in the semiconductor fin or coupled to the semiconductor fin, wherein the drain and the source are located at different sides of the gate; and
a first drift region or a well doped with second conductive type impurities, the first drift region or the well being formed in the semiconductor fin at least between the drain and the gate.

2. The high voltage multigate device of claim 1, further comprising a body region doped with first conductive type impurities, surrounding the source and separating the source and the gate.

3. The high voltage multigate device of claim 1, wherein the gate includes multiple separated gate plates.

4. The high voltage multigate device of claim 1, further comprising an isolation structure formed in the semiconductor fin, partially or totally in a region surrounded by the gate.

5. The high voltage multigate device of claim 1, further comprising a second drift region with second conductive type impurities, the second drift region being formed in the semiconductor fin at least between the source and the gate.

6. The high voltage multigate device of claim 1, wherein the source and the drain are located on the same plane or on different planes.

7. A method for manufacturing a high voltage multigate device, comprising:
forming a semiconductor fin doped with first conductive type impurities;
forming a dielectric layer overlaying a portion of the semiconductor fin;
forming a gate overlaying the dielectric layer;
forming a drain doped with second conductive type impurities in the semiconductor fin or coupled to the semiconductor fin;
forming a source doped with second conductive type impurities in the semiconductor fin or coupled to the semiconductor fin, wherein the drain and the source are located at different sides of the gate; and
forming a first drift region or a well doped with second conductive type impurities in the semiconductor fin at least between the drain and the gate.

8. The method of claim 7, further comprising: forming a body region doped with first conductive type impurities, surrounding the source and separating the source and the gate.

9. The method of claim 7, wherein the gate includes multiple separated gate plates.

10. The method of claim 7, further comprising: forming an isolation structure in the semiconductor fin partially or totally in a region surrounded by the gate.

11. The method of claim 7, further comprising: forming a drift region with second conductive type impurities, the drift region being formed in the semiconductor fin at least between the source and the gate.

12. The method of claim 7, wherein the source and the drain are located on the same plane or on different planes.
